(19) United States
(12) Patent Application Publication
(10) Pub. No.: US 2005/0041700 A1
(43) Pub. Date: Feb. 24, 2005

(54) Multiwavelength semiconductor laser

(76) Inventor: Kazuya Tsunoda, Zama-shi (JP)

Correspondence Address: GRAY CARY WARE & FREIDENRICH LLP, 2000 UNIVERSITY AVENUE, E. PALO ALTO, CA, 94303-2248, US

(21) Appl. No.: 10/915,754

(22) Filed: Aug. 10, 2004

(30) Foreign Application Priority Data
Aug. 20, 2003 (JP) P2003-296422

(51) Int. Cl. H01S 3/10; H01S 5/00

(52) U.S. Cl. 372/23; 372/50

(57) ABSTRACT

Disclosed is a multiwavelength semiconductor laser capable of emitting first and second laser beams of different wavelengths from first and second positions of an emission surface, comprising a first light-emitting section emitting the first laser beam of which light flux cross-sectional shape at the first position is a first elliptical shape; and a second light-emitting section emitting the second laser beam of which light flux cross-sectional shape at the second position separate from the first position is a second elliptical shape having a major axis and a minor axis displaced substantially in parallel from a major axis and a minor axis of the first elliptical shape.

### CROSS REFERENCE TO RELATED APPLICATIONS

This application is based upon and claims the benefit of priority from the prior Japanese Patent Application No. 2003-296422, filed on Aug. 20, 2003; the entire contents of which are incorporated herein by reference.

### BACKGROUND

1. Field of the Invention

The present invention relates to a multiwavelength semiconductor laser capable of separately emitting laser beams of plural wavelengths, and more particularly to a high power multiwavelength semiconductor laser suitable for the emission of laser beams for recording on recording media.

2. Description of the Related Art

A laser beam used for recording on a DVD (digital versatile disc) has a wavelength of 650 nm as standard, and a laser beam for recording on a CD (compact disc) has a wavelength of 780 nm as standard. Generally, a laser beam of a shorter wavelength is suitable for recording at a high density because its spot becomes smaller after the laser beam is narrowed. In view of the physical characteristics of the recording media, it is generally required that output power is 80 mW or more when recording with a 650 nm laser beam for a DVD and output power is 150 mW or more when recording with a 780 nm laser beam for a CD.

A device capable of recording in both DVDs and CDs is configured to have separately, for example, a 650 nm semiconductor laser and a 780 nm semiconductor laser as pickup heads to emit onto a disk by switching between the laser beam for a DVD and the laser beam for a CD and can place both emitted beams on the same optical axis by a beam splitter (half mirror) or the like.

There is also disclosed a technique configured to position two laser beams on the same optical axis by using an optical axis correcting plate instead of the beam splitter (e.g., Japanese Patent Laid-Open Application No. 2002-319176). According to the structure disclosed in this publication, the 650 nm semiconductor laser and the 780 nm semiconductor laser are not positioned separately as parts, but a double wavelength semiconductor laser configured of the same chip can be used. An example structure of the double wavelength semiconductor laser capable of separately emitting laser beams of two wavelengths is described in, for example, Japanese Patent Laid-Open Application No. 2002-299764.

[Patent Document 1]
Japanese Patent Laid-Open Application No. 2002-319176

[Patent Document 2]
Japanese Patent Laid-Open Application No. 2002-299764

Matters needed to be considered when a semiconductor laser is used for recording on a DVD include a possibility of causing reflections leading to disturbance because of high-output light which extends the radiation to the adjacent row of pits depending on the shape or direction of the spot narrowed on the disk surface. Performance of tracking servo is affected depending on a degree of reflection causing the disturbance. Generally, the shape of the spot on the disk becomes an elliptical shape with a major axis and a minor axis interchanged to those that the light flux cross-section of the emitted light (a far view image) of the semiconductor laser has. When it is configured to record (to arrange recording pits) in the direction of the minor axis of the elliptical shape of the spot, advantageous recording can be made in view of a linear density, but the above-described apprehension occurs. Where recording is to be made (to arrange the recording pits) in the direction of the major axis of the elliptical shape, occurrence of the above-described adverse effect is eliminated substantially, but there is a possibility that a necessary recording linear density cannot be dealt with.

Accordingly, to solve such a problem, the minor axis of the elliptical shape is tilted with respect to the row of recording pits to perform recording (namely, to record by setting to the middle). But, when this setting to the middle is made by the double wavelength semiconductor laser for both the wavelengths, a problem is caused. Specifically, the double wavelength semiconductor laser has a slightly different emitting position (e.g., about 100 μm) for each wavelength because of its configuration (see the above-described cited references), and when an optical system that the difference in emitting position is retained as a difference in radiation positions on the disk is used, the minor axis of one spot is tilted with respect to the row of recording pits, so that the other spot is also tilted with respect to the row of recording pits in the same way, but the position of the other spot is displaced in the peripheral direction of the disk.

But, the optical system cannot be generally adjusted to be optimum for the spot displaced in the peripheral direction of the disk. In other words, the optical system is configured to be finely movable in a focus direction to form a focal point and in the radial direction of the disk for tracking by a servo mechanism but fixed when it is adjusted once in the peripheral direction of the disk because there is no effect on the functions. It means that when the optical system is optimized in the peripheral direction of the disk for one of the wavelengths, the adjustment of the optical system cannot secure optimality for the other wavelength. In other words, when the double wavelength semiconductor laser is used for recording, the recording characteristics may be degraded comprehensively.

To avoid the above disadvantage, there may be considered, for example, a way of configuring two types of optical systems and switching between them for each wavelength used. But, the mechanisms become complex, the optical pickup head cannot be made compact, and the cost cannot be reduced. The above-described cited references have no description about a possibility that the radiation extends to the adjacent row of pits depending on the shape or direction of the spot narrowed on the disk to cause reflections resulting in disturbance.

### SUMMARY

The multiwavelength semiconductor laser according to one aspect of the present invention is a multiwavelength semiconductor laser capable of emitting first and second laser beams of different wavelengths from first and second positions of an emission surface, comprising a first light-emitting section emitting the first laser beam of which light flux cross-sectional shape at the first position is a first elliptical shape; and a second light-emitting section emitting the second laser beam of which light flux cross-sectional shape at the second position separate from the first position is a second elliptical shape having a major axis and a minor axis displaced substantially in parallel from a major axis and a minor axis of the first elliptical shape.

### BRIEF DESCRIPTION OF THE DRAWINGS

FIG. 1 is a schematic perspective view showing a structure of a multiwavelength semiconductor laser according to an embodiment of the present invention.

FIG. 2A and FIG. 2B are schematic views (a top view and a side view) showing example structures for packaging the multiwavelength semiconductor laser shown in FIG. 1.

FIG. 3 is a schematic view showing an example structure of applying the multiwavelength semiconductor laser (packaged product) shown in FIG. 2A and FIG. 2B to a write/read optical system.

FIG. 4A and FIG. 4B are schematic views illustrating the shapes of spots formed on the surface of a disk, respectively.

FIG. 5 is a schematic perspective view showing a structure of a multiwavelength semiconductor laser according to another embodiment of the present invention.

FIG. 6 is a schematic front view showing a structure of a multiwavelength semiconductor laser according to still another embodiment of the present invention.

FIG. 7A and FIG. 7B are schematic views showing an example structure of applying a multiwavelength semiconductor laser according to yet another embodiment of the present invention to a write/read optical system.

### DETAILED DESCRIPTION

(Description of Examples)

The embodiments of the invention will be described with reference to the drawings but it is to be understood that the drawings are provided for illustration only and the invention is not limited to the drawings.

The multiwavelength semiconductor laser according to an aspect of the present invention has the elliptical shapes on the emission surfaces of first and second laser beams from different emitting positions in a positional relationship that their major axes and minor axes are parallel to each other (excepting on a straight line). Where the emitting positions have the above relationship, the positional relationship of radiation spots on a disk is aligned on a straight line in the radial direction of the disk, and the minor axes of the elliptical shapes of the radiation spots can be tilted to the direction of recording pits (in other words, when the minor axes are tilted to the direction of recording pits, the positions of the radiation spots are aligned on the straight line in the radial direction). Therefore, it becomes possible to adjust the optical system to secure optimality for both wavelengths, and the multiwavelength semiconductor laser capable of emitting recording laser beams of individual wavelengths, which do not deteriorate the recording characteristics, can be provided.

As an implement mode of the present invention, the space between the minor axis of the first elliptical shape and the minor axis of the second elliptical shape is 50 μm or more. A structure of emitting multiplewavelength laser beams by, for example, a single chip requires a prescribed degree of space for fabrication of individual light-emitting sections. At present, this space adopted in a double wavelength semiconductor laser for the individual wavelengths of a DVD and a CD is 110 μm as standard. In this mode, the above-described prescribed degree of space is determined to be 50 μm or more from the viewpoint of future use. The space can be set to have an error of, for example, ±10 μm or less. If the error is large, an adjustment range absorbed/dealt by the optical system becomes excessively large to cause an influence on the cost.

As an implement mode, the space between the major axis of the first elliptical shape and the major axis of the second elliptical shape is in a range of 0.40 μm to 131 μm. Then, tan⁻¹ (major axis space/minor axis space) becomes 20 to 50 degrees in connection with the space (110 μm) between the minor axis of the first elliptical shape and the minor axis of the second elliptical shape as standard for the double wavelength semiconductor laser of the individual wavelengths for a DVD and a CD. Such angles are also angles formed by the minor axis of the radiation spot on the disc to the row of recording pits. Specifically, the angle of the minor axis to the row of recording pits is determined to be 20 degrees to 50 degrees as a direction of radiation spot on the disk, so that a possibility of extending the radiation to an adjacent row of pits is considerably reduced, and the elimination of reflections causing disturbance is expected.

As an implement mode, the first light-emitting section and the second light-emitting section may be configured as a section formed on the same chip, respectively. If the two light-emitting sections are formed on the same chip, their relative positional relationship can be secured with higher accuracy.

As an implement mode, the first light-emitting section and the second light-emitting section may be included in separate chips. By producing them as separate chips, their low cost and high productivity may be expected.

The multiwavelength semiconductor laser as an implement mode may be further provided with a third light-emitting section which emits a third laser beam whose light flux cross-sectional shape on the emission surface of a third position on an extension from the first position to the second position is a third elliptical shape having the major axis and the minor axis each displaced in parallel from the major axis and the minor axis of the second elliptical shape. By configuring as above, the third light-emitting section can be made to emit, for example, light of a wavelength of 405 nm so that a single-body multiwavelength semiconductor laser can be applied to a use for recording on next-generation DVDs.

The multiwavelength semiconductor laser as an implement mode may be further comprised of a hologram element which is disposed at a position allowing the transmission and passage of the first and second laser beams, and a light detector which is disposed at a position where the laser beams reach after they are incident on the hologram element in a direction opposite to the first and second laser beams having passed through the hologram element and are diffracted. By configuring as above, the emission of the high-output laser beam for recording and the light detection by emitting the laser beams for playing back and by receiving the reflected light can be made by a compact device.

As an implement mode, the light detector may be disposed at a point of intersection where the individual laser beams incident in the opposite direction reach after diffracting. Because the laser beams have different wavelengths, the diffraction directions are different, and there is a point of intersection of them. Therefore, where the light detector is disposed at the point of intersection, a single light detector is sufficient. Thus, the cost can be reduced.

The multiwavelength semiconductor laser as an implement mode may be further provided with a mount member on which the individual chips are fixed and which has a difference in level on the mounting surface that fixes the individual chips. This is one example structure of securing the above-described space between the minor axis of the first elliptical shape and the minor axis of the second elliptical shape.

The multiwavelength semiconductor laser as an implement mode may be further provided with a mount member that fixes the chips and lead pins electrically conducting to the input/output terminals of the fixed chips. In other words, packaging is carried out.

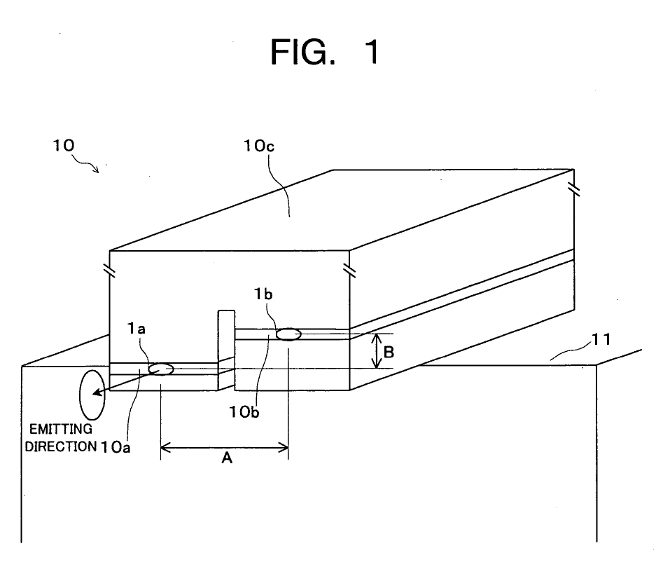

Based on the above descriptions, the embodiments of the present invention will be described with reference to the drawings. FIG. 1 is a schematic perspective view showing a structure of the multiwavelength semiconductor laser according to one embodiment of the invention. This multiwavelength semiconductor laser is a so-called edge-emitting type double wavelength semiconductor laser, the current direction is vertical from a double wavelength semiconductor laser 10, and the laser beams are emitted from its front end. An active layer 10a and an active layer 10b are positioned horizontally on vertically different levels. The active layer 10a (the first light-emitting section) emits a laser beam of 650 nm for a DVD, and the active layer 10b (the second light-emitting section) emits a laser beam of 780 nm for a CD. These laser beams can be emitted selectively by turning on/off the current supply to the individual sections.

A semiconductor substrate side electrode 10c is commonly disposed on the top surface of the double wavelength semiconductor laser 10, and individual electrodes (not shown) are disposed on the bottom surface to emit the individually laser beams. The active layers 10a, 10b and the multilayer structure (e.g., an optical guide layer, a clad layer, etc.) disposed in their vertical direction are separated by a groove as shown in the drawing. The active layers 10a, 10b and the multilayer structure disposed in their vertical direction are known well, and their description in detail is omitted. The bottom surface (opposite to the semiconductor substrate side) of the double wavelength semiconductor laser 10 is partly fixed to a submount 11 which also serves as a heat sink. Thus, the double wavelength semiconductor laser 10 is disposed to protrude slightly from the submount 11.

A light flux cross-section 1a on the emission surface (front end surface) of the laser beam of 650 nm and a light flux cross-section 1b of the laser beam of 780 nm have a horizontally long elliptical shape (a near view image) as shown in the drawing. This horizontally long elliptical shape becomes a vertically long elliptical shape (a far view image) as it becomes far from the emission surface. Because it is also known well that the semiconductor laser is produced to have the emitted light with the described elliptical shape (or the semiconductor laser having the described emitted shape can be produced as a result), its description in detail is omitted. The laser beam of 650 nm has output power of 80 mW or more, and the laser beam of 780 nm has output power of 150 mW or more. These values can be experimentally derived, for example, as a value capable of recording from the physical properties of the individual disks without any problem.

Besides, this double wavelength semiconductor laser 10 has the active layers 10a, 10b formed on vertically different positions. Thus, the output position of the laser beam of 650 nm and the output position of the laser beam of 780 nm have a difference in level in the vertical direction. In other words, both the laser beams on the emission surface have a relationship that the minor axes of the elliptical shapes are displaced in parallel by a distance A, and the major axes of the elliptical shapes are displaced in parallel by a distance B. Specifically, the distances A, B are, for example, 110 μm and 40 to 131 μm respectively.

The distance A=110 μm is adopted as standard for a conventional double wavelength semiconductor laser (reading only) for a DVD and a CD. When A=110 μm, B is determined to be 40 to 131 μm, and tan⁻¹(B/A) becomes 20° to 50°. When such an angle is determined for the double wavelength semiconductor laser, the minor axis of the radiation spot on the disk is adjusted to the same angle to the row of recording pits, and the spot positions of the two wavelengths are aligned with the radial direction of the disk (details will be described later).

The distance A can be generally set to an appropriate value such that a monolithic semiconductor laser can be produced with ease. For example, it can be set to a value of 50 μm or more for production. The distance B can be calculated and set by B=A*tan θ (provided θ0=20° to 50°) after the distance A is determined. The production error of the distance A is determined to be, for example, ±10 μm or less. This production error is an error of the angle of the radiation spot's minor axis to the row of recording pits on the disk from a determined angle or displacement of the radiation spots of the individual wavelengths on the disk in the peripheral direction of the disk. The former relates to a margin until the generation of reflections which causes disturbance as the radiation extends to the adjacent rows of pits, and the latter relates to the cost of the optical system because the range of adjustment which is absorbed and dealt by the optical system becomes large.

The specific method of having different forming positions of the active layers 10a, 10b in the vertical direction in the double wavelength semiconductor laser 10 may be considered that the monolithic structure of this embodiment is assumed as a precondition, the semiconductor substrate is previously provided with a stepped surface by, for example, etching or another method, and a semiconductor laser having a double hetero junction structure is laminated on the individual stepped surfaces. Another method not predicated on the monolithic structure can also be employed (described later).

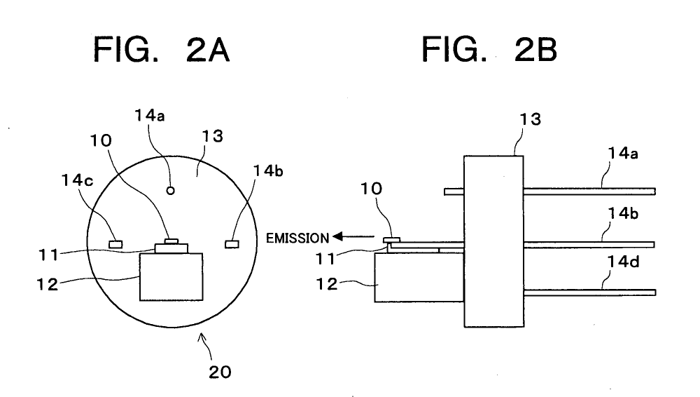

FIG. 2A and FIG. 2B are schematic views showing an example structure for packaging the double wavelength semiconductor laser shown in FIG. 1. FIG. 2A is a top view and FIG. 2B is a side view, wherein a sealing cap is not shown. The same reference numerals are allotted to the same elements as those shown in FIG. 1.

As shown in FIG. 2A and FIG. 2B, a double wavelength semiconductor laser 20 (package product) has the submount 11, on which the double wavelength semiconductor laser 10 (chip) is mounted, disposed on one surface of a rectangular parallelopiped shaped stem block 12. The top surface of a flat cylindrical stem 13 is in contact with one surface of the stem block 12 which is adjacent to the surface on which the submount 11 is disposed, and the stem block 12 is fixed. Thus, an emission optical axis of the double wavelength semiconductor laser 10 is positioned substantially on the axis of the cylindrical stem 13 as shown in the drawings. The stem 13 has a diameter of 5.6 mm for example.

Individual lead pins 14a, 14b, 14c, 14d are disposed through the stem 13, and the individual lead pins 14a, 14b, 14c, 14d on the side of the stem block 12 and the individual electrodes (not shown) of the double wavelength semiconductor laser 10 are electrically connected by, for example, a bonding wire (not shown) or the like, respectively. A sealing cap (not shown) is disposed on the stem 13 on the side of the stem block 12 of the stem 13 so to wholly cover the double wavelength semiconductor laser 10 (chip) and others.

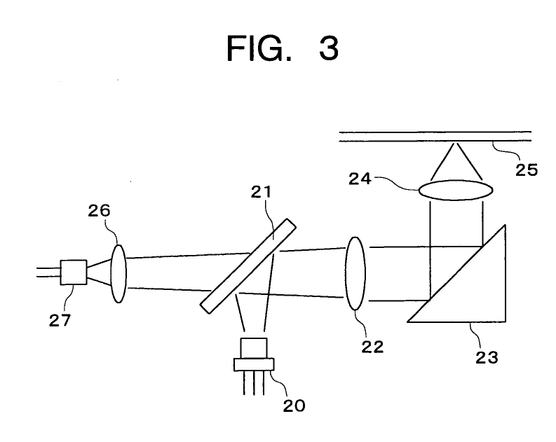

FIG. 3 is a schematic view showing an example structure of applying the double wavelength semiconductor laser 20 (package product) shown in FIG. 2A and FIG. 2B to a write/read optical system. When writing (recording), a laser beam (selectively either of the wavelengths) emitted by the double wavelength semiconductor laser 20 is guided to and reflected from a half mirror 21, and the reflected laser beam is entered into a collimator lens 22 and converted into a parallel beam. Besides, the laser beam converted into the parallel beam is guided to and reflected from a rising mirror 23 so to enter an objective lens 24. The objective lens 24 narrows the incident laser beam to form a radiation spot suitable for recording on a disk surface 25. Thus, writing on the disk surface 25 is performed.

When reading (playback) is to be carried out, the laser beam is emitted, guided and radiated in the same way (except that the light output is reduced significantly) as is the case of the above-described writing. And, the reflected light is sequentially guided to the objective lens 24, the rising lens 23, the collimator lens 22, the half mirror 21 and a convex lens 26 for concentration of light and entered into a light detector 27. Thus, information written on the disk surface 25 is read.

By the optical system shown in FIG. 3, read and write from and to a DVD-R/-RW/-ROM and a CD-R/-RW/-ROM (read only from a CD-ROM) can be made by the same optical pickup, wherein R is recordable, RW is rewritable and ROM is read only memory. An optical pickup having the same functions, which is capable of recording on both DVDs and CDs, can be realized by a simple structure because the parts and optical system for radiating on the disk by switching between the laser beam for DVDs and the laser beam for CDs, for example, the semiconductor lasers of 650 nm and 780 nm and the beam splitter (half mirror) for positioning both the emitted lights on the same optical axis are not needed.

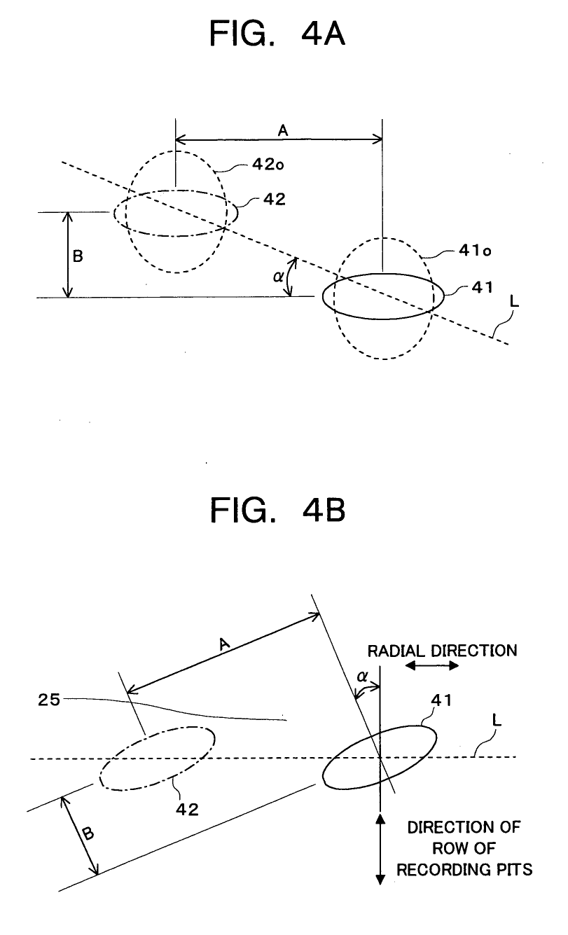

FIG. 4A and FIG. 4B are schematic views illustrating the shape of the radiation spot formed on the disk surface 25 by the optical system shown in FIG. 3. FIG. 4A virtually shows that adjustment is conducted to make the direction of the minor axis of the radiation spot formed on the disk surface 25 same to that of the row of recording pits. This adjustment is not performed in practice but illustrated for convenience of description. In FIG. 4A, reference numeral 410 is a light flux cross-section of a 650 nm laser beam (showing the shape when observed in the forward direction at the front of the objective lens 24), and reference numeral 420 is a light flux cross-section of a 780 nm laser beam (showing the shape when observed in the forward direction at the front of the objective lens 24). They correspond to the elliptical shapes on the emission surface of the double wavelength semiconductor laser 10 (chip) and have an elliptical shape with the minor axis and the major axis interchanged (the interchange of the minor axis and the major axis is due to a difference between a near view image and a far view image).

These light flux cross-sections are narrowed by the objective lens 24 to form radiation spots 41, 42 in the elliptical shape on the disk surface 25 as shown in the drawing. As a result of the narrowing, the elliptical shapes of the radiation spots 41, 42 become opposite in the direction of the major axis and the minor axis to the light flux cross-section at the front of the objective lens 24. Distance A and distance B in FIG. 4A correspond to the distance A and the distance B shown in FIG. 1 respectively, and B/A (=tan α) is retained (θ is used instead of a in the description referring to FIG. 1). A line connecting the centers of the radiation spots 41, 42 is virtually determined as straight line L for convenience of description.

The positional relationship between the radiation spots 41, 42 is supplementarily described. As shown in FIG. 3, the laser beam emitted from the double wavelength semiconductor laser 20 is reflected from two positions, namely the half mirror 21 and the rising mirror 23, so that their right-side-left relationship is retained. The retained right-side-left relationship is observed in the forward direction of light from the rear, so that the right-side-left relationship is opposite to that of FIG. 1 as shown in FIG. 4A.

FIG. 4B shows radiation spots and their positional relationship when optical adjustment is performed in practice. Specifically, this optical adjustment is performed so that a direction of the minor axis of the radiation spot 41 (42) has an angle α to the row of recording pits on the disk surface 25. As a result, the straight line L connecting the centers of the radiation spots 41, 42 agrees with the radial direction on the disk surface 25. For example, this adjustment can be made by turning the double wavelength semiconductor laser 20 about the axis by α as shown in FIG. 3.

When the direction of the minor axis of the radiation spot 41 (42) is made (tilted) to have an angle α to the row of recording pits on the disk surface 25, a possibility that reflections causing disturbance are induced because of the extension of the radiation to the adjacent row of pits is reduced in comparison with the case of α=0°. The effect of the disturbance reflections is considered because the laser beam has considerably high power as a state peculiar to the time of writing. Considering the above effect, it is appropriate to tilt so to have the angle α of, for example, 20° to 50° in practice.

In the adjusted state shown in FIG. 4B, the straight line L agrees with the radial direction on the disk surface 25 (namely, the two radiation spots 41, 42 are not displaced in the peripheral direction of the disk), so that it is possible to move the objective lens 24 in the direction naturally movable for tracking and to perform appropriate optical adjustment in compliance with both the laser beams. As a result, a disadvantage involved in the adjustment, e.g., a disadvantage that the adjustment of the optical system for either of the laser beams is not optimum or the adjustment of the optical system for both laser beams becomes lax, which is caused when the two radiation spots 41, 42 are displaced in the peripheral direction of the disk, is eliminated.

It is seen from the above description that the angle θ formed by the spaces A, B of the minor axes and the major axes of the light-emitting sections of the double wavelength semiconductor laser 10 described with reference to FIG. 1 is set to be equal to the angle α to be formed by the direction of the minor axis of the radiation spot 41 (42) with respect to the row of recording pits on the disk surface 25. Thus, the double wavelength semiconductor laser capable of separately emitting the laser beams of two wavelengths become possible to emit the recording laser beams not degrading the recording characteristics at the individual wavelengths.

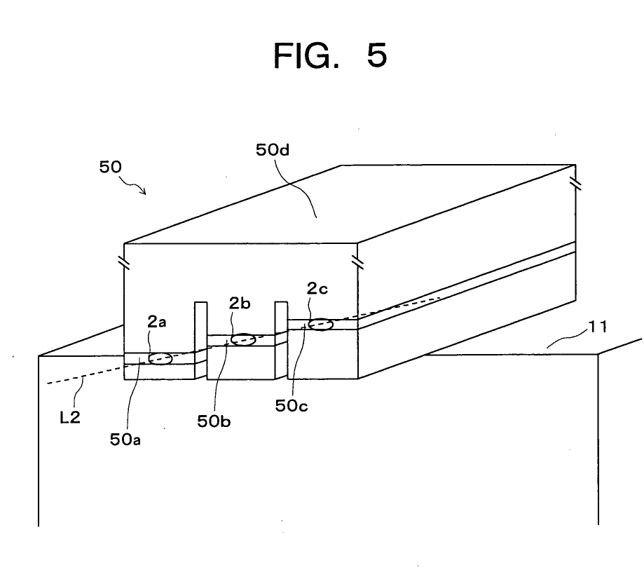

Then, the multiwavelength semiconductor laser according to another embodiment of the present invention will be described with reference to FIG. 5. FIG. 5 is a schematic perspective view showing a structure of the multiwavelength semiconductor laser according to this embodiment of the invention. The multiwavelength semiconductor laser of this embodiment has a structure different from that of the double wavelength semiconductor laser shown in FIG. 1 on the point that an active layer 50c is disposed as a third light-emitting section. The submount 11 is substantially the same as that shown in FIG. 1.

This multiwavelength semiconductor laser is an edge-emitting type three-wavelength semiconductor laser, wherein electric current flows in the vertical direction of the three-wavelength semiconductor laser 50, and laser beams are emitted from the front end. Among active layers 50a, 50b and 50c which are disposed horizontally with a difference in level in the vertical direction, the active layer 50a (first light-emitting section) emits a 650 nm laser beam for DVDs, the active layer 50b (second light-emitting section) emits a 780 nm laser beam for CDs, and the active layer 50c (third light-emitting section) emits, for example, a 0.405 nm laser beam for high-density recording DVDs. These beams can be emitted selectively by turning on/off the supply of current to the individual sections.

A semiconductor substrate side electrode 50d is commonly disposed on the top surface of the three-wavelength semiconductor laser 50, and separate electrodes (not shown) are disposed on the bottom surface for emission of the individual laser beams. Besides, a third light-emitting section is made to have an emitting position on their extension L2 while an emitting positional relationship of the two laser beams shown in FIG. 1 is maintained. The three laser beams on the emission surface satisfy the relationship that, for example, the minor axes of the elliptical shapes of individual light flux cross-sections 2a, 2b, 2c are displaced in parallel by the distance A1, and the major axes of the elliptical shapes of the individual light flux cross-sections 2a, 2b, 2c are displaced in parallel by the distance B1. Specifically, the distances A1 and B1 can be determined to be 110 μm and 40 to 131 μm respectively.

According to the three-wavelength semiconductor laser of this embodiment, a three-wavelength semiconductor laser capable of separately emitting the laser beams of three wavelengths can emit recording laser beams which do not degrade the recording characteristics at individual wavelengths. Reasons are substantially the same as those described about the double wavelength semiconductor laser 10 with reference to FIG. 2A, FIG. 2B, FIG. 3, FIG. 4A and FIG. 4B, and details will be omitted. By the optical system shown in FIG. 3, a write/read optical system with provisions for three wavelengths is realized, and its component reduction effect is further enhanced as compared with that of the optical system for two wavelengths.

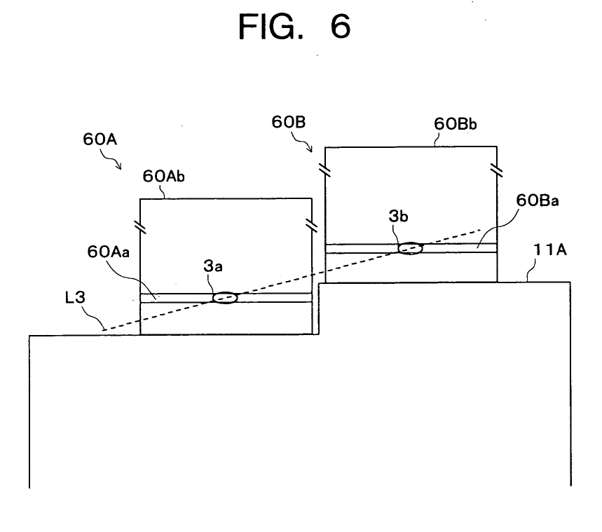

Then, the multiwavelength semiconductor laser according to still another embodiment of the present invention will be described with reference to FIG. 6. FIG. 6 is a schematic front view showing a structure of the multiwavelength semiconductor laser according to this embodiment of the invention. Different from the double wavelength semiconductor laser shown in FIG. 1, this embodiment provides two separate chips as the semiconductor lasers and fixes them on a submount 11A having a difference in level on the surface.

A semiconductor laser 60A and a semiconductor laser 60B are single wavelength semiconductor lasers. For example, the semiconductor laser 60A emits a laser beam of 650 nm, and the semiconductor laser 60B emits a laser beam of 780 nm. The semiconductor laser 60A is provided with an active layer 60Aa as a light-emitting section, and the active layer 60Aa emits a laser beam having a light flux cross-section 3a of a horizontally long elliptical shape (a near view image). The semiconductor laser 60B is provided with an active layer 60Ba as a light-emitting section, and the active layer 60Ba emits a laser beam having a light flux cross-section 3b of a horizontally long elliptical shape (a near view image).

Semiconductor substrate side electrodes 60Ab, 60Bb are disposed on the top surfaces of the semiconductor lasers 60A, 60B, and individual laser beam emitting electrodes (not shown) are disposed on the bottom surfaces. The bottom surfaces (opposite to the semiconductor substrate side) of the semiconductor lasers 60A, 60B are partly fixed to a submount 11A which also serves as a heat sink. Thus, the semiconductor lasers 60A, 60B are disposed to protrude slightly from the submount 11A.

In this embodiment, the positional relationship between a light flux cross-section 3a and a light flux cross-section 3b is determined, so that the minor axes mutually have the distance A, and the major axes mutually have the distance B as described with reference to FIG. 1, and a straight line L3 connecting the centers of the light flux cross-section 3a and the light flux cross-section 3b has inclination of B/A with the major axis of the light flux cross-section 3a (3b). By arranging as described above, the semiconductor lasers 60A, 60B are fixed onto the submount 11A, and the semiconductor laser of this embodiment provides the same effects as those of the embodiments described with reference to FIG. 1 to FIG. 4B.

The same effects can be obtained without using the semiconductor laser which emits multiwavelength laser beams by the monolithic structure, and the device as a semiconductor laser chip has a simple structure, so that a production load can be reduced accordingly. Naturally, the structure using the individual semiconductor laser chips for the individual wavelengths can also be applied to the emission of high-output laser beams of three wavelengths as shown in FIG. 5.

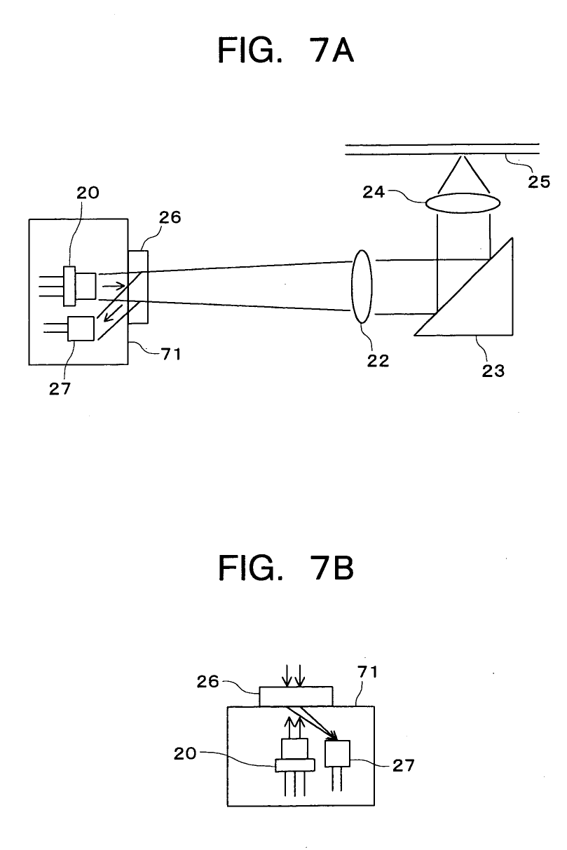

The multiwavelength semiconductor laser according to yet another embodiment of the present invention will be described with reference to FIG. 7A and FIG. 7B. FIG. 7A and FIG. 7B are schematic views showing an example structure of applying a multiwavelength semiconductor laser according to this embodiment of the present invention to a write/read optical system. In FIG. 7A and FIG. 7B, the same reference numerals are allotted to the same elements as those already described above, and their descriptions are omitted wherever possible. In this embodiment, the above-described double wavelength semiconductor laser 20 with parts for improving added values added to its periphery and unitized is used.

Specifically, as shown in FIG. 7A, the double wavelength semiconductor laser 20 is unitized as a double wavelength semiconductor laser 71, and the double wavelength semiconductor laser 71 has a light detector 27 and a hologram element 26 other than the double wavelength semiconductor laser 20. The hologram element 26 is disposed in a position to allow transmission and passage of two wavelength laser beams from the double wavelength semiconductor laser 20, and the laser beams reflected from the disk surface 25 are entered in an opposite direction to the hologram element 26.

When the laser beams reflected from the disk surface 25 are entered in the opposite direction into the hologram element 26, diffraction occurs, and the diffracted light travels in a direction different from the double wavelength semiconductor laser 20. Thus, the light detector can be positioned in its traveling direction, and reading by optical detection at the pertinent position can be made by a single unit. Therefore, the unit is made to be highly functional and its added value can be enhanced.

The diffracted light by the hologram element 26 has a different diffraction direction depending on the wavelengths, and when the laser beams reflected from the disk surface 25 are entered in a direction opposite to the emission, a diffraction angle can be determined for each wavelength, and their point of intersection can be made present as shown in FIG. 7B. Then, when it is configured to dispose the light detector 27 at the point of intersection, light beams of both wavelengths can be detected efficiently by a single light detector 27. In other words, cost reduction and miniaturization can be realized at the same time.

When configured to have the single light detector 27, a distance between the laser beams emitted from the double wavelength semiconductor laser 20 relates to the position where the light detector 27 is disposed (namely, the distances between the light detector 27 and the hologram element 26 and the double wavelength semiconductor laser 20). Therefore, this distance (namely, √(A²+B²) in FIG. 1) may be determined so that the light detector 27 is disposed without involving any disadvantage, and the double wavelength semiconductor laser 20 is produced with the determined distance. For example, when the emitted laser beams have a distance of about 200 μm to about 300 μm between them, each distance between the light detector 27 and the hologram element 26 and the double wavelength semiconductor laser 20 becomes small and has a size of not mutually interfering. Thus, the unit becomes compact and favorable.

It is to be understood that the present invention is not limited to the specific embodiments thereof illustrated herein, and various modifications may be made without departing from the scope of the claims of the invention.

1. A multiwavelength semiconductor laser capable of emitting first and second laser beams of different wavelengths from first and second positions of an emission surface, comprising:
a first light-emitting section emitting the first laser beam of which light flux cross-sectional shape at the first position is a first elliptical shape; and
a second light-emitting section emitting the second laser beam of which light flux cross-sectional shape at the second position separate from the first position is a second elliptical shape having a major axis and a minor axis displaced substantially in parallel from a major axis and a minor axis of the first elliptical shape.

2. The multiwavelength semiconductor laser as set forth in claim 1, wherein a space between the minor axis of the first elliptical shape and the minor axis of the second elliptical shape is 50 μm or more.

3. The multiwavelength semiconductor laser as set forth in claim 1, wherein a space between the major axis of the first elliptical shape and the major axis of the second elliptical shape is 40 μm to 131 μm.

4. The multiwavelength semiconductor laser as set forth in claim 1, wherein the first light-emitting section and the second light-emitting section are regions respectively formed on a same chip.

5. The multiwavelength semiconductor laser as set forth in claim 1, wherein the first light-emitting section and the second light-emitting section are included in separate chips respectively.

6. The multiwavelength semiconductor laser as set forth in claim 1, further comprising a third light-emitting section which emits a third laser beam whose light flux cross-sectional shape on a emission surface of a third position on an extension from the first position to the second position is a third elliptical shape-having a major axis and a minor axis each displaced in parallel from the major axis and the minor axis of the second elliptical shape.

7. The multiwavelength semiconductor laser as set forth in claim 1, further comprising:
a hologram element which is disposed at a position where the first and second laser beams are transmitted and passed; and
a light detector which is disposed at a position where laser beams each entered into the hologram element in a direction opposite to that of the first and second laser beams having passed through the hologram element are diffracted to reach.

8. The multiwavelength semiconductor laser as set forth in claim 7, wherein the light detector is single and disposed at a point of intersection where the individual laser beams incident in the opposite direction are diffracted to reach.

9. The multiwavelength semiconductor laser as set forth in claim 5, further comprising a mount member which mounts to fix the separate chips and has its mount surface fixing the separate chips provided with a stepped surface.

10. The multiwavelength semiconductor laser as set forth in claim 4, further comprising:
a mount member that mounts to fix the chips; and
lead pins electrically conducting to input and output terminals of the fixed chips.

11. The multiwavelength semiconductor laser as set forth in claim 5, further comprising:
a mount member that mounts to fix the chips; and
lead pins electrically conducting to input and output terminals of the fixed chips.
